(19) United States
(12) Patent Application Publication
(10) Pub. No.: US 2026/0262208 A1
(43) Pub. Date: Sep. 3, 2026

(54) ROUTING MEMORY DEVICE SIGNALS WITH DIFFERENT INTERCONNECT LAYERS OF A FRONT SIDE INTERCONNECT STRUCTURE AND A BACK SIDE INTERCONNECT STRUCTURE

(71) Applicant: Taiwan Semiconductor Manufacturing Company, Ltd., Hsin-Chu (TW)

(72) Inventors: Chia-Hao Pao, Kaohsiung City (TW); Yung-Ting Chang, New Taipei City (TW); Kian-Long Lim, Hsinchu City (TW); Ping-Wei Wang, Hsinchu (TW)

(21) Appl. No.: 19/068,190

(22) Filed: Mar. 3, 2025

(51) Int. Cl. H10B 10/00

(52) U.S. Cl. CPC H10B 10/125; H10B 10/18

(57) ABSTRACT

An electronic memory device includes a non-memory-cell region and a memory-cell region. The non-memory-cell and the memory-cell region include circuitry formed in a substrate. The memory-cell region includes first, second, and third segments. The first segment is located closest to the non-memory-cell region in a top view. The second and third segments are each located farther from the non-memory-cell region than the first segment. A first interconnect structure is disposed over a first side of the substrate in a cross-sectional side view. The first interconnect structure includes first and second interconnect layers. The first and second interconnect layers are configured to route a memory signal to the first and second segments, respectively. A second interconnect structure is disposed over a second side of the substrate. The second interconnect structure includes a third interconnect layer configured to route the memory signal to the third segment.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As integrated circuit devices get scaled down, device parasitics (e.g., parasitic resistance and/or parasitic capacitance) may become a concern. For example, a memory device (e.g., a static random access memory (SRAM)) may utilize a metal line to carry memory device signals (e.g., a bit line signal) for the memory cell array of the memory device. However, if such a metal line extends too far into the memory cell array, and the memory cell array is long, the parasitics associated with such a metal line may adversely impact the performance of the memory device, such as speed and/or power consumption. Therefore, while memory device designs have been generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A is a diagrammatic perspective view of a semiconductor device.

FIG. 1B is a diagrammatic top view of a semiconductor device.

FIG. 1C is a cross-sectional side view of a semiconductor device.

FIG. 2 is a circuit schematic of an SRAM cell.

FIGS. 3-4 are block diagrams of a top view of a memory device according to various aspects of the present disclosure.

FIGS. 5A-5C illustrate the revision of an original IC layout design to generate a revised IC layout design according to various embodiments of the present disclosure.

FIG. 6 illustrates a cross-sectional side view of a portion of a memory device according to various embodiments of the present disclosure.

FIGS. 7A-7C illustrate a revised IC layout design according to various embodiments of the present disclosure.

FIGS. 8A and 8B illustrate planar top views of a front side and a back side of a portion of an IC layout according to various embodiments of the present disclosure.

FIG. 9 is a block diagram of a semiconductor fabrication system.

FIG. 10 is a flowchart illustrating a method of fabricating an electronic memory device according to various embodiments of the present disclosure.

FIG. 11 is a flowchart illustrating a method of revising an IC layout design according to various embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to Integrated Circuit (IC) Devices, and more particularly, to improving the performance of electronic memory devices by reducing the effects of loading and/or device parasitics. In that regard, electronic memory devices such as static random access memory (SRAM) devices can be implemented using field-effect transistors (FETs), such as three-dimensional fin-shaped FETs (FinFETs) or gate-all-around (GAA) devices. Electronic memory devices, such as SRAM devices, may utilize a metal line in an interconnect structure to route memory device signals (e.g., a bit line signal) to the memory cell arrays of the electronic memory device. However, as IC fabrication progresses to more advanced technology nodes, the effects of the device parasitics (e.g., parasitic resistance or parasitic capacitance) may become more pronounced. For example, the metal line used to perform the memory device signal routing may become sufficiently thin, such that parasitic resistance associated with such a metal line may begin to significantly degrade the performance of the electronic memory device. In addition, such a metal line may generate parasitic capacitance with other nearby conductive components, which may also degrade the performance of the electronic memory device. Furthermore, these effects may worsen when a single metal line is used to route the memory device signal substantially throughout an entire length of the memory cell array of the electronic memory device. In particular, the memory cell arrays at the farther end of the metal line may experience even greater parasitic resistance and/or capacitance.

To address the issues discussed above, the present disclosure utilizes the metal lines from multiple interconnect layers located above and below a substrate to carry out the memory device signal routing to different regions of the electronic memory device. For example, a metal line in a metal-0 layer in a front side interconnect structure may be used to route the bit line signal to the memory cell arrays of a nearby region (e.g., nearby relative to a location of a region of the electronic memory device from which the metal line originates, such as a periphery circuit region) of the electronic memory device. A metal line in a metal-2 layer in the front side interconnect structure may be used to route the bit line signal to the memory cell arrays of an intermediate region of the electronic memory device. A metal line in a metal-0 layer in the back side interconnect structure may be used to route the bit line signal to the memory cell arrays of a far region of the electronic memory device.

These metal lines of the different interconnect layers may also be configured to have different widths. For example, the metal line from the metal-2 layer may be configured to have a thicker width than the metal line from the metal-0 layer in the front side of the interconnect structure, since the metal line from the metal-2 layer is supposed to route the bit line signal to a farther region, which may otherwise increase the parasitic resistance. The thicker width of the metal line from the metal-2 layer may help reduce the parasitic resistance. In addition, the bit line signal meant to be routed to the farther region may also be able to bypass potential interferences from the nearby region, since it does not have to travel through the metal lines of the metal-0 layer. Similarly, the metal line from the metal-0 layer in the back side interconnect structure may be configured to have a thicker width than the metal line from the metal-0 layer in the front side of the interconnect structure, and possibly even a thicker width than the metal line from the metal-2 layer in the front side of the interconnect structure, since this metal line is supposed to route the bit line signal to an even farther region. The utilization of the metal-2 layer of the front side interconnect structure and the metal-0 layer of the back side interconnect structure to route the bit line signal may also lead to reduced parasitic capacitance, since these layers are located farther away from other conductive components that could form a parasitic capacitor with the metal lines, where the parasitic capacitance is inversely correlated with distance between two conductive components.

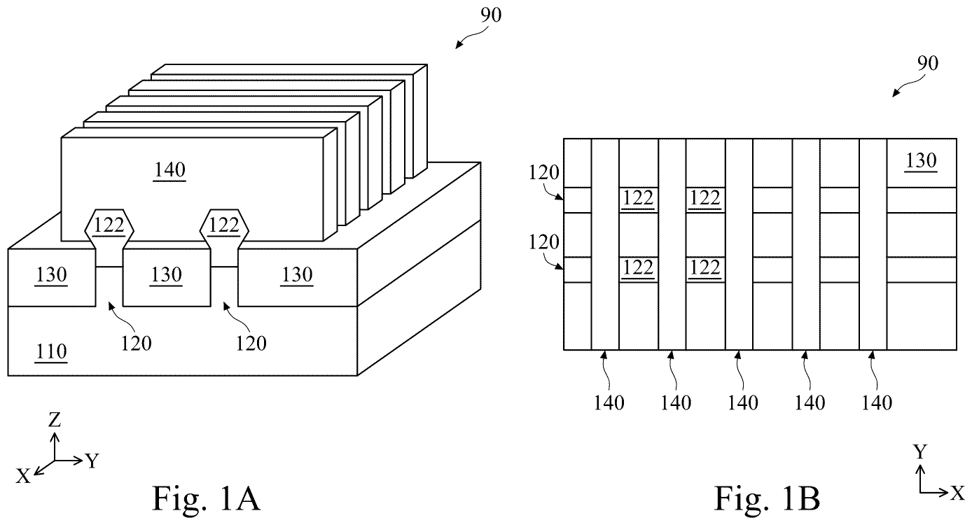

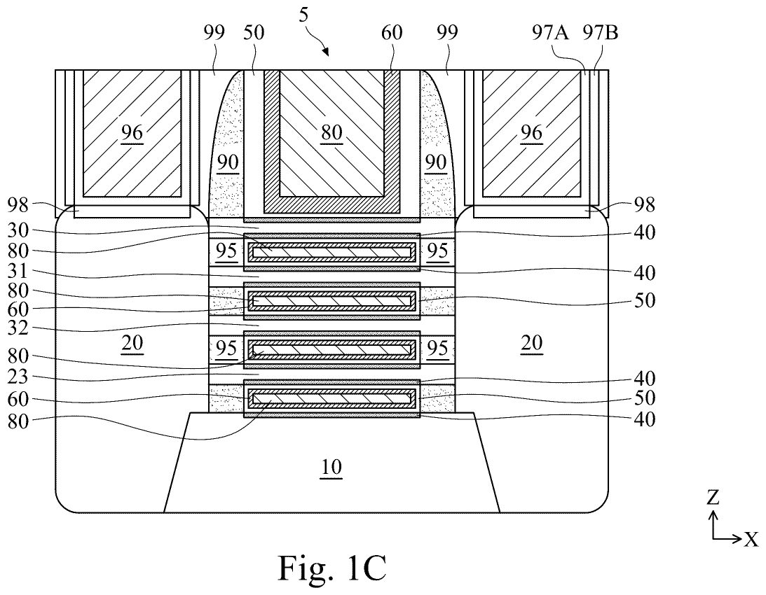

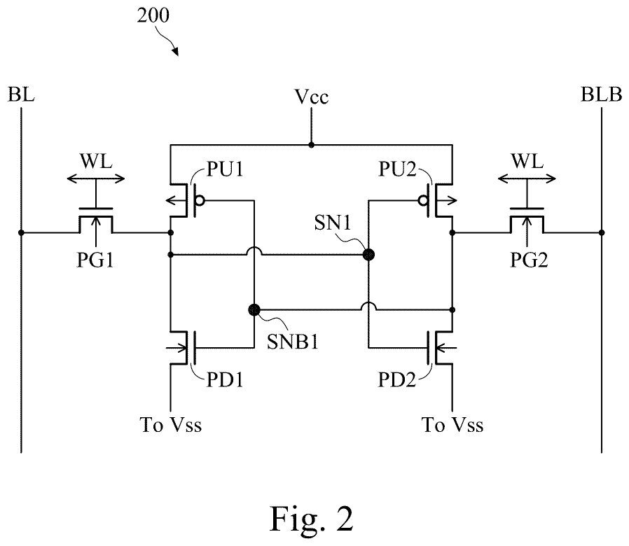

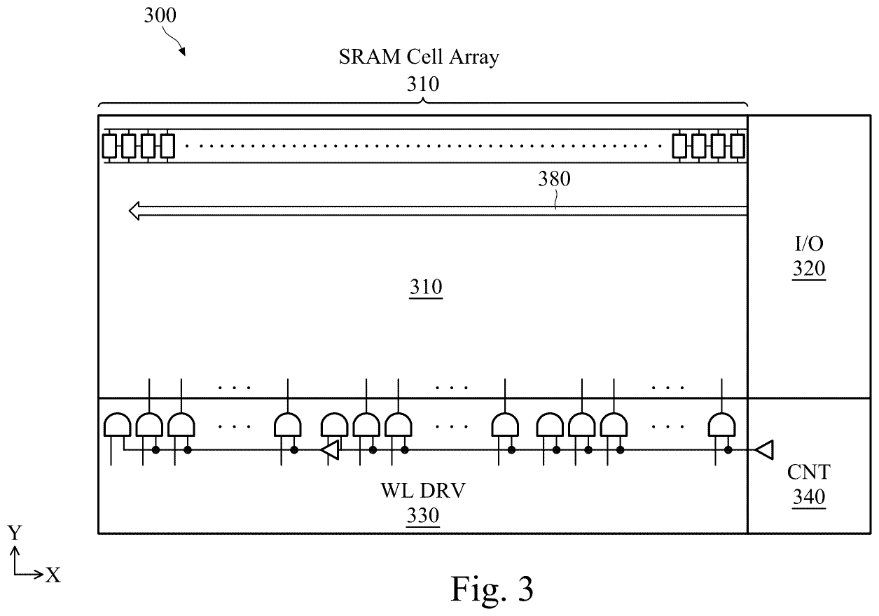

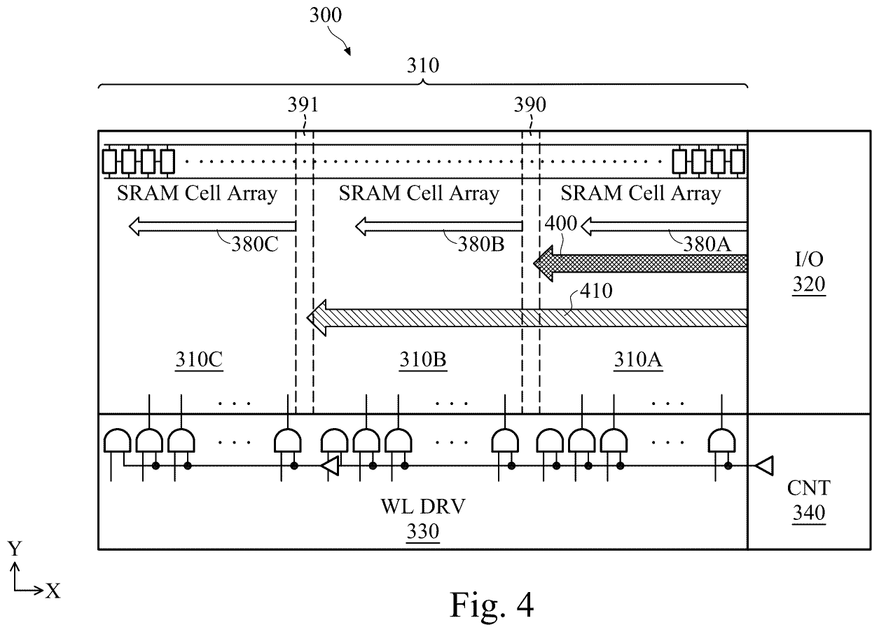

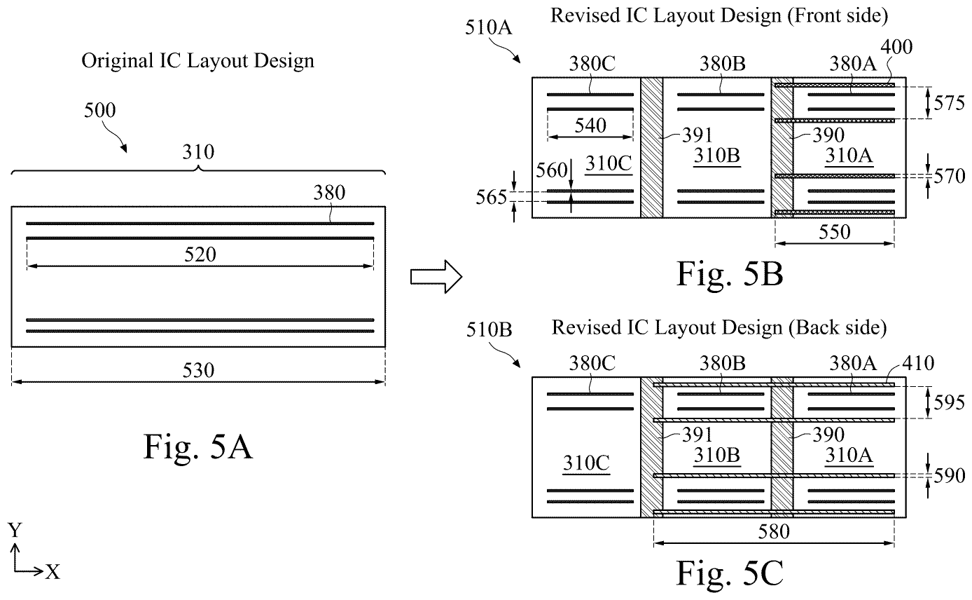

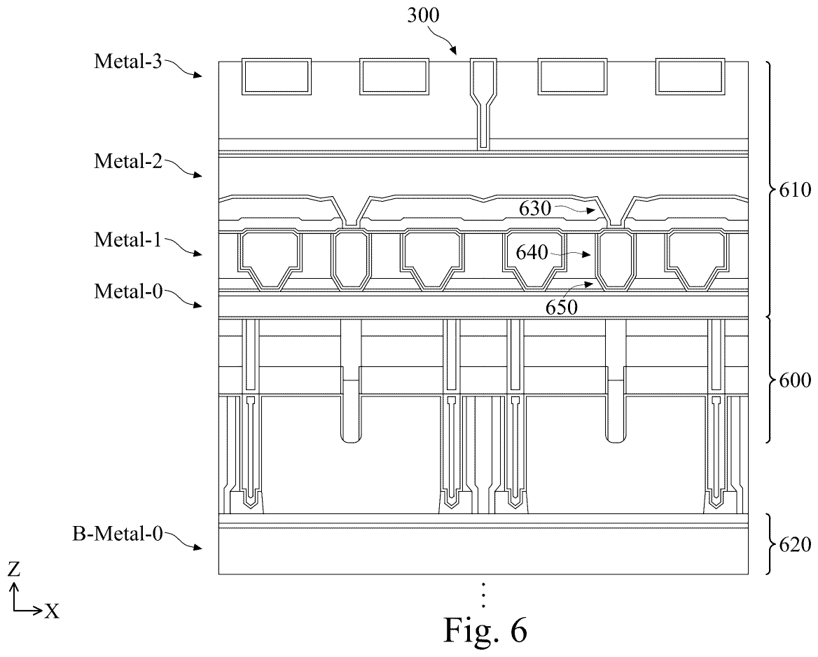

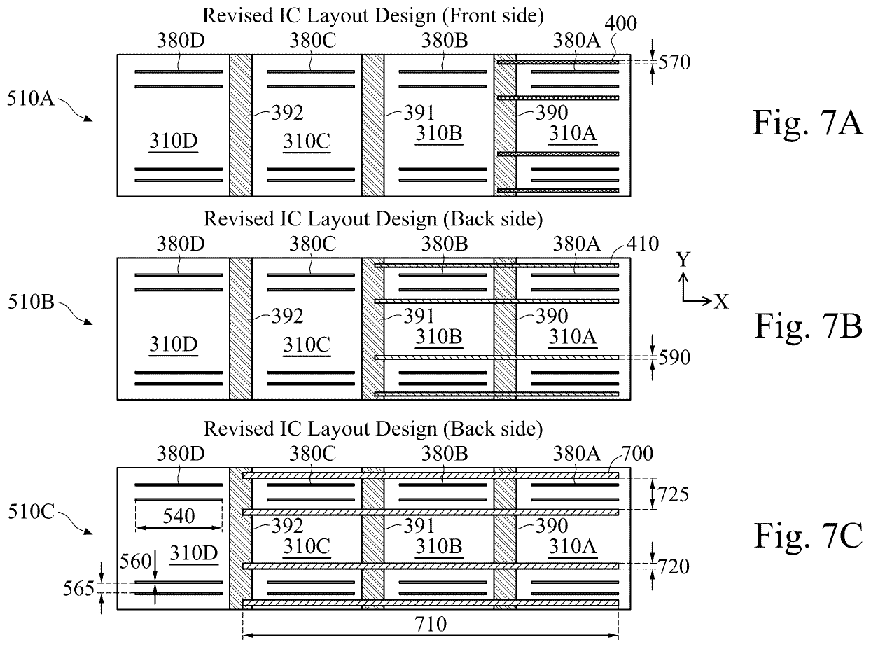

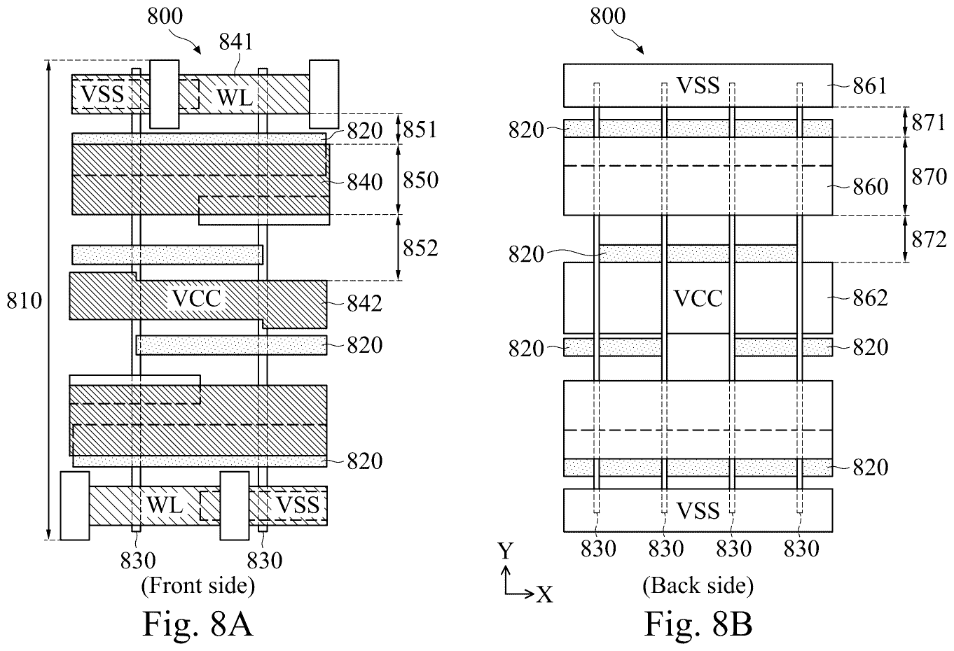

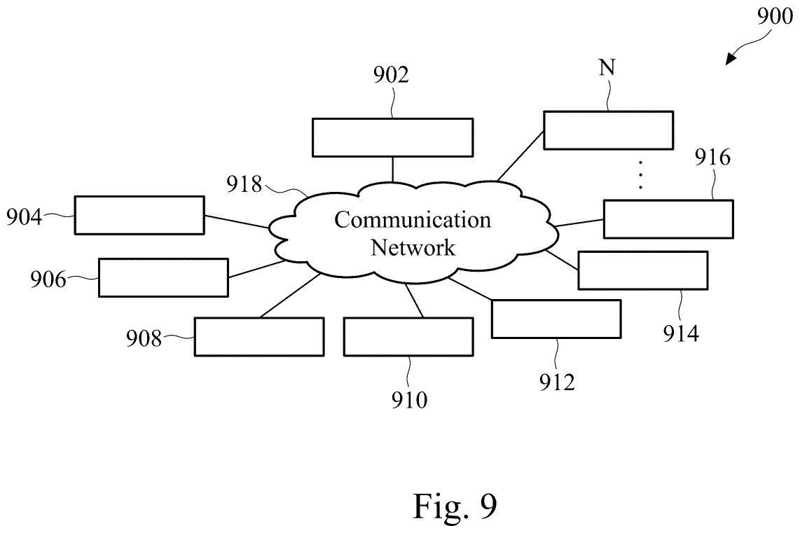

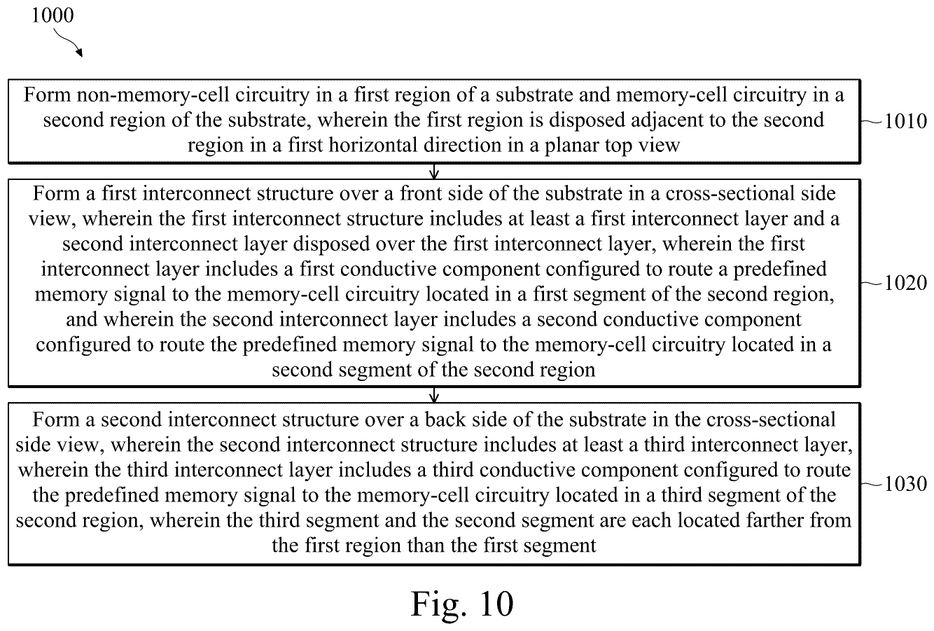

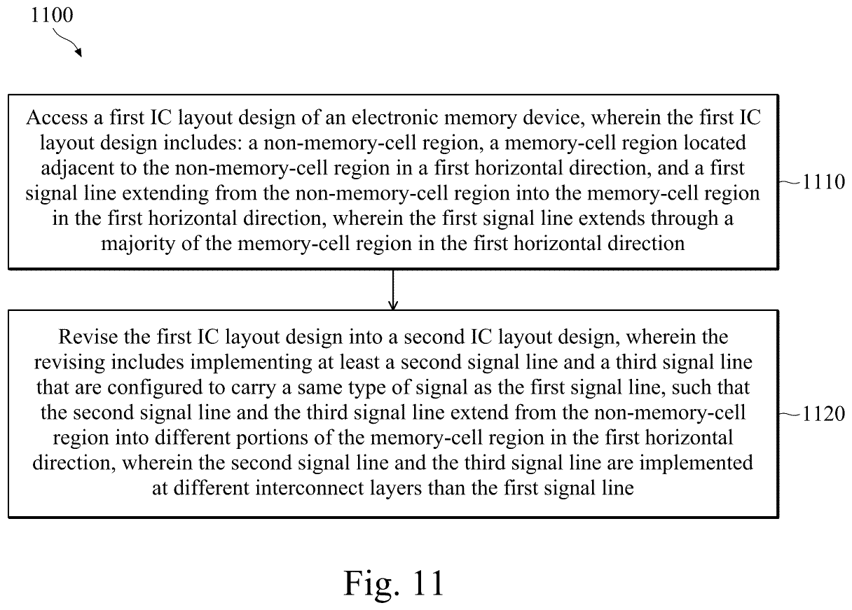

The various aspects of the present disclosure are now discussed in greater detail below with reference to FIGS. 1A-1C, 2-4, 5A-5C, 6, 7A-7C, 8A-8B, and 9-11. In more detail, FIGS. 1A-1C will describe the basic structures of example transistors (such as FinFET and GAA devices) that could be used to implement an electronic memory device. FIG. 2 will describe an example electronic memory device. FIGS. 3-4 are block diagrams of a top view of a memory device according to various aspects of the present disclosure. FIGS. 5A-5C are top views of an IC design layout according to various aspects of the present disclosure. FIG. 6 is a cross-sectional side view of an IC device according to various embodiments of the present disclosure. FIGS. 7A-7C are top views of an IC design layout according to various aspects of the present disclosure. FIGS. 8A-8B are top views of a front side and a back side of an SRAM cell according to various aspects of the present disclosure. FIG. 9 is a block diagram of a semiconductor fabrication system according to various embodiments of the present disclosure. FIG. 10 is a flowchart illustrating a method of fabricating a memory device according to various embodiments of the present disclosure. FIG. 11 is a flowchart illustrating a method of revising an IC layout design according to various embodiments of the present disclosure.

Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells.

In the embodiment of FIGS. 1A-1B, the IC device 90 includes a FinFET device. In that regard, a FinFET device is a fin-like field-effect transistor device. FinFET devices have been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices for a portion of, or the entire IC chip.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions, including nano-structures, are formed on the substrate 110. The active regions are elongated fin-like structures that protrude upwardly out of the substrate 110. The protrusion structure 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

It is also understood that the various aspects of the present disclosure discussed below may apply to multi-channel devices such as Gate-All-Around (GAA) devices. FIG. 1C illustrates a diagrammatic cross-sectional side view of a portion of an IC device 5 fabricated according to embodiments of the present disclosure, where the IC device 5 is a gate-all-around (GAA) device and may be referred to as a GAA device 5 hereinafter. It is understood that the GAA device 5 may be an NFET in some embodiments, or it may be a PFET in other embodiments.

Referring to FIG. 1C, the cross-sectional view of the GAA device 5 is taken along an X-Z plane, where the X-direction (same X-direction as in FIG. 1A) is the horizontal direction, and the Z-direction (same Z-direction as in FIG. 1A) is the vertical direction. The GAA device 5 includes a fin structure 10, which may be similar to the fin structure 120 discussed above. In some embodiments, the fin structure 10 includes silicon. The GAA device 5 includes source/drain features 20, which may be similar to the source/drain features 122 discussed above. In embodiments where the GAA device 5 is an NFET, the source/drain features 20 include silicon phosphorous (SiP). In embodiments where the GAA device 5 is a PFET, the source/drain features 20 include silicon germanium (SiGe).

The GAA device 5 includes a plurality of channels, for example channels 30-33 as shown in FIG. 1C. The channels 30-33 each include a semiconductive material, for example silicon or a silicon compound. The channels 30-33 are nanostructures (e.g., having sizes that are in a range of a few nanometers) and may also each have an elongated shape and extend in the X-direction. In some embodiments, the channels 30-33 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 30-33 may be different from each other. For example, a length of the channel 30 may be less than a length of the channel 31, which may be less than a length of the channel 32, which may be less than a length of the channel 33. In some embodiments, each of the channels 30-33 may not have uniform thicknesses.

In some embodiments, a spacing (e.g., measured in the Z-direction) between the channels 30-33 (each channel from adjacent channels) is in a range between about nanometers (nm) and about 12 nm. In some embodiments, a thickness (e.g., measured in the Z-direction) of each of the channels 30-33 is in a range between about 5 nm and about nm. In some embodiments, a width (e.g., measured in the Y-direction of FIG. 1A) of each of the channels 30-33 is in a range between about 15 nm and about 150 nm. A plurality of interfacial layers (ILs) 40 may also be formed on the upper and lower surfaces of the channels 30-33.

The GAA device 5 also includes gate structures that are disposed over and in between the channels 30-33. The gate structures may include gate dielectric layers 50. In some embodiments, the gate dielectric layers 50 include a high-k gate dielectric. The gate structures further include one or more work function metal layers 60. In embodiments where the GAA device 5 is an NFET, the one or more work function metal layers 60 include N-type work function metal layers, such as TiAlC. In embodiments where the GAA device 5 is a PFET, the one or more work function metal layers 60 include P-type work function metal layers, such as TiN.

The gate structures also include fill metals 80. In the portion of the gate structure formed over the channels 30-33, the fill metal 80 are formed over the one or more work function metal layers 60. The one or more work function metal layers 60 have a U-shape and wrap around the fill metal 80, and the gate dielectric layer 50 also has a U-shape and wrap around the one or more work function metal layers 60. In portions of the gate structures formed between the channels 30-33, the fill metal 80 is circumferentially surrounded (in the cross-sectional view) by the one or more work function metal layers 60, which is then circumferentially surrounded by the gate dielectric layer 50. It is understood that the gate structures may also include a glue layer that is formed between the one or more work function metal layers 60 and the fill metal 80 to increase adhesion. However, for reasons of simplicity, such a glue layer is not specifically illustrated herein.

The GAA device 5 also includes gate spacers 90 and inner spacers 95 that are disposed on sidewalls of the gate dielectric layer 50. The inner spacers 95 are also disposed between the channels 30-33. The gate spacers and the inner spacers 95 may include a dielectric material, for example a low-k material such as SiOCN, SiON, SiN, or SiOC.

The GAA device 5 further includes source/drain contacts 96 that are formed over the source/drain features 20. The source/drain contacts 96 may include a conductive material such as cobalt, copper, aluminum, tungsten, or combinations thereof. The source/drain contacts 96 are surrounded by barrier layers, for example barrier layers 97A and 97B, which help prevent or reduce diffusion of materials from and into the source/drain contacts 96. In some embodiments, the barrier layer 97A includes TiN, and the barrier layer 97B includes SiN. A silicide layer 98 may also be formed between the source/drain features 20 and the source/drain contacts 96, so as to reduce the source/drain contact resistance. The silicide layer 98 may contain a metal silicide material, such as cobalt silicide in some embodiments.

The GAA device 5 further includes an interlayer dielectric (ILD) 99. The ILD 99 provides electrical isolation between the various components of the GAA device 5, for example between the gate structures and the source/drain contacts 96.

GAA devices may also offer advantages such as better chip area efficiency, improved carrier mobility, etc. As such, advanced IC chips may be implemented using the GAA devices as well. However, it is understood that the present disclosure is not limited to any particular number of devices or device regions, or to any particular device configurations, unless otherwise claimed. For example, although FinFET devices or GAA devices have been described as potential transistors that could be used to implement the IC chip or a portion thereof, the concepts of the present disclosure discussed in more detail below may also apply to IC chips implemented using planar FET devices as well.

It is understood that the present disclosure is not limited to any particular number of devices or device regions, or to any particular device configurations, unless otherwise claimed. For example, although the IC device 90 is illustrated as a three-dimensional FinFET device in FIGS. 1A-1B and as a GAA device in FIG. 1C, the concepts of the present disclosure may also apply to planar FET devices.

FIG. 2 illustrates an example type of an electronic memory device in which transistors such as planar transistors, FinFET transistors, or GAA transistors may be implemented. In the particular example of FIG. 2, a circuit schematic of an example Static Random-Access Memory (SRAM) device is illustrated, for example, as a single-port SRAM cell (e.g., 1-bit SRAM cell) 200. The single-port SRAM cell 200 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 200 includes six transistors in the illustrated embodiment, it may also be referred to as a 6T SRAM cell. Regardless, transistors such as the FinFET or GAA transistors may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to a signal line referred to as bit line (BL) through pass-gate transistor PG1, and the complementary first storage node SNB1 is coupled to complementary signal line referred to as bit line bar (BLB) through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line (WL) signal, which may be used to select a specific row of memory cells. SRAM devices such as the SRAM cell 200 may be implemented using “planar” transistor devices, with FinFET devices, and/or with GAA devices.

FIG. 3 is a block diagram of a portion of an electronic memory device 300 in which the SRAM cell 200 may be implemented. For example, the electronic memory device 300 may include a SRAM cell array region 310 for implementing a plurality of SRAM devices (e.g., the SRAM cell 200 of FIG. 1). As SRAM cell arrays, the SRAM devices in the SRAM cell array region may include substantially identical blocks (e.g., arrays) of SRAM cells as repeating circuit units. In some embodiments, the SRAM devices in the SRAM cell array region 310 are implemented using the FinFET transistors and/or the GAA transistors discussed above with reference to FIGS. 1A-1C. However, it is understood that other types of transistors (e.g., planar transistors) may also be used to implement the SRAM devices in the SRAM cell array region 310 as well.

The electronic memory device 300 may also include various non-memory-cell circuit regions that surround the periphery of the SRAM cell array region 310. As such, these non-memory-cell circuit regions may also be referred to as periphery regions or periphery circuits. In the example shown in FIG. 3, the periphery region of the electronic memory device 300 includes an input/output (I/O) region 320, a word line driver (WL DRV) region 330, and a control circuit (CNT) region 340. In some embodiments, the I/O region 320 contains electrical circuitry that handles the input/output for the SRAM devices of the SRAM cell array region 310, the WL DRV region 330 contains electrical circuitry that drives the word line for the SRAM devices of the SRAM cell array region 310, and the CNT region 340 contains electrical circuitry that controls the electrical operation of the SRAM devices of the SRAM cell array region 310. As discussed above, the I/O region 320, the WL DRV region 330, and the CNT region 340 may be collectively or individually referred to as periphery regions.

Although not specifically illustrated herein for reasons of simplicity, it is understood that the electronic memory device 300 may further includes other types of non-memory-cell regions in other embodiments, such as a standard cell region that includes logic circuits for performing Boolean logic operations, an eFuse region that includes microscopic electronic fuses configured to enable dynamic real-time reprogramming of chips, or a general-purpose input/output (GPIO) region configured to handle the input/output between the electronic memory device 300 and the devices external to the electronic memory device 300. It is also understood that the transistors of the I/O region 320, the WL DRV region 330, the CNT region 340, and/or other types of non-memory-cell regions may also be implemented using the FinFET transistors and/or the GAA transistors discussed above.

The block diagram in FIG. 3 is illustrated in a planar top view defined by an X-axis and a Y-axis horizontally (which may or may not be the same as the X-direction and Y-direction discussed above with reference to FIGS. 1A-1C). The I/O region 320 is disposed directly adjacent to the SRAM cell array region 310 in the X-direction, the WL DRV region 330 is disposed directly adjacent to the SRAM cell array region 310 in the Y-direction, and the CNT region 340 is disposed directly adjacent to the WL DRV region 330 in the X-direction and directly adjacent to the I/O region 320 in the Y-direction.

The block diagram in FIG. 3 also includes a memory signal line 380 configured to carry a specified type of memory signal. For example, the memory signal line 380 may be configured to carry a bit line (BL) signal in the illustrated embodiment, and as such, the memory signal line 380 may be interchangeably referred to as a BL signal line 380 hereinafter. However, it is understood that the memory signal line 380 may carry other types of memory device signals in other embodiments, such as bit line bar (BLB) or another suitable signal.

The BL signal line 380 may include a metal line (e.g., a conductive component) formed in a multi-layer interconnect structure, where the metal line is configured to carry or route electrical signals such as the BL signal from a non-memory-cell region (e.g., the I/O region 320) to a memory-cell region (e.g., the SRAM cell array region 310). However, as the size of the SRAM cell array region 310 increases, the length of the BL signal line 380 may also increase, which could lead to problems associated with loading and/or parasitic effects. For example, if the size of an SRAM array is greater than or equal to 128 bits, then the relatively long length of the corresponding BL signal line 380 may suffer from noticeable loading and/or parasitic effects. The parasitic resistance of the BL signal line 380 may worsen as the length of the BL signal line 380 increases and/or when the width of the BL signal line 380 decreases. Parasitic capacitance may be formed by the coupling of the BL signal line 380 and other nearby conductive components (e.g., two conductive plates with a dielectric material in between), which may also worsen as the length of the BL signal line 380 increases and/or when the distance between the BL signal line 380 and other nearby conductive components decreases. As a result of the loading and/or parasitics, the device performance of the electronic memory device 300 may degrade. For example, the electronic memory device 300 may operate at a slower speed, dissipate more power, generate more heat, and/or have a shorter lifespan.

To address the problems discussed above, the present disclosure revises the IC layout design of electronic memory device 300 by implementing a plurality of additional signal lines to help carry/route the BL signal. For example, FIG. 4 illustrates a block diagram of a portion of the electronic memory device 300 according to the revised IC layout design. For reasons of consistency and clarity, similar components appearing in FIGS. 3-4 are labeled the same.

Referring now to FIG. 4, the electronic memory device 300 still includes the SRAM cell array region 310, but it is divided into multiple segments. For example, the SRAM cell array region 310 is divided into segments 310A, 310B, and 310C in the embodiment shown in FIG. 4. The segment 310A is located the closest to the I/O region 320, the segment 310B is located farther away from the I/O region 320 than the segment 310A, and the segment 310C is located the farthest from the I/O region 320 (e.g., farther than both the segment 310A and the segment 310B). Each of the segments 310A-310C may still include the same type of SRAM cell array as the SRAM cell array region 310 of FIG. 3.

A respective segment of the BL signal line 380 is implemented in each of the segments 310A-310C. For example, rather than having a relatively long BL signal line 380 (as was the case in FIG. 3), a BL signal line segment 380A is implemented in the segment 310A of the SRAM cell array region 310, a BL signal line segment 380B is implemented in the segment 310B of the SRAM cell array region 310, and a BL signal line segment 380C is implemented in the segment 310C of the SRAM cell array region 310, where each of the BL signal line segments 380A-380C is shorter in length than the BL signal line 380 of FIG. 3 in the X-direction. The smaller length of each of the BL signal line segments 380A-380C may allow for reduced loading and/or parasitic resistance and capacitance, which in turn helps to improve device performance such as speed and/or power consumption.

The SRAM cell array region 310 further implements additional memory signal lines to help route the specified memory signal (e.g., the BL signal herein) to the different segments of the SRAM cell array region 310. In the embodiment illustrated herein, since the specified memory signal carried by the memory signal line 380 is a BL signal, these additional memory signal lines are also configured to carry the BL signal. For example, a BL signal line 400 is implemented to help route the BL signal directly from the I/O region 320 to the segment 310B of the SRAM cell array region 310, while bypassing the BL signal line segment 380A in the segment 310A. Similarly, a BL signal line 410 is implemented to help route the BL signal directly from the I/O region 320 to the segment 310C of the SRAM cell array region 310, while bypassing the BL signal line segment 380A in the segment 310A, as well as the BL signal line segment 380B in the segment 310B. This is made possible by implementing the BL signal line 400 and the BL signal line 410 in different interconnect layers than the BL signal line segments 380A-380C. For example, whereas the BL signal lines 380A-380C may be implemented in a metal-0 interconnect layer of a front side interconnect structure, the BL signal line 400 may be implemented in a metal-2 interconnect layer (i.e., two levels above the metal-0 interconnect layer) of the front side interconnect structure, and the BL signal line 410 may be implemented in a B-metal-0 interconnect layer of a back side interconnect structure, where the front side interconnect structure and the back side interconnect structure are located on opposite sides of the substrate in which the electrical circuitry of the electronic memory device 300 is formed.

As discussed above, the fact that the BL signal lines 400 and 410 are located in different interconnect layers than the BL signal line segments 380A-380C allow for the BL signal to be delivered directly to the segments 310B and 310C of the SRAM cell array region 310 while bypassing potential interferences from the electrical circuitry and/or the BL line segments 380A-380B. For example, parasitic capacitance associated with the BL signal line 400 and the BL signal line 410 may be reduced, since the distance between the other conductive components and these BL signal lines 400 or 410 is increased due to the fact that the BL signal lines 400 or 410 is implemented in an interconnect layer that is farther away from the other conductive components. In addition, the BL signal line 400 and the BL signal line 410 are not only configured to have a greater dimension than the BL signal line segments 380A-380C in the X-direction, but in the Y-dimension as well. In other words, the BL signal line 400 and the BL signal line 410 are each wider than the BL signal line segments 380A-380C. The wider width of the BL signal line 400 and the BL signal line 410 allows them to have a reduced parasitic resistance compared to the BL signal line segments 380A-380C. As a result, device performance may further be improved.

Still referring to FIG. 4, the SRAM cell array region 310 includes a plurality of middle strap regions disposed between the segments 310A-310C. For example, a middle strap region 390 is located between the segments 310A and 310B of the SRAM cell array region 310, and a middle strap region 391 is located between the segments 310B and 310C of the SRAM cell array region 310. The middle strap regions 390 and 391 are configured to facilitate electrical routing. For example, the BL signal line 400 may extend (in the X-direction) from the I/O region 320 to the middle strap region 390. The middle strap region 390 may include one or more conductive vias and/or metal lines that are configured to be electrically coupled to the BL signal line 400, as well as the BL signal line segment 380B in the SRAM cell array region segment 310B. As such, the BL signal may be routed from the I/O region 320, through the BL signal line 400 and the conductive vias and/or metal lines of the middle strap region 390 (while bypassing the segment 310A of the SRAM cell array region 310), to the SRAM cell array circuitry in the SRAM cell array region segment 310B. Similarly, the middle strap region 391 may include one or more conductive vias and/or metal lines that are configured to be electrically coupled to the BL signal line 410, as well as the BL signal line segment 380C in the SRAM cell array region segment 310C. As such, the BL signal may be routed from the I/O region 320, through the BL signal line 410 and the conductive vias and/or metal lines of the middle strap region 391 (while bypassing the segments 310A-310B of the SRAM cell array region 310), to the SRAM cell array circuitry in the SRAM cell array region segment 310C.

FIGS. 5A-5C illustrates an IC layout designs revision process according to embodiments of the present disclosure. In more detail, FIG. 5A illustrates an original IC layout design 500, and FIGS. 5B and 5C illustrate a revised IC layout design 510A and 510B based on the original IC layout design 500. The original IC layout design 500 and the revised IC layout design 510A-510B are all illustrated as planar top views, where the planar top view corresponds to a horizontal plane defined by the X-direction and the Y-direction. In some embodiments, the original IC layout design 500 may be in the format of a Graphic Data System (GDS) file, which includes solder masks, geometry, layers, component labels, and the general layout of a circuit. The GDS file may have a binary format in some embodiments. In some embodiments, the original IC layout design 500 may be generated by an IC design house, which may then send the original IC layout design to an IC fabrication facility (e.g., an IC foundry). The IC fabrication facility may access and revise the original IC layout design 500 to generate a revised IC layout design, which in this case is collectively made up of the revised IC layout designs 510A and 510B.

Referring now to FIG. 5A, the original IC layout design 500 includes an IC layout design for the SRAM cell array region 310 discussed above with reference to FIG. 3. For reasons of consistency and clarity, similar components appearing in FIGS. 3-4 and 5A-5C will be labeled the same. The original IC layout design 500 includes a plurality of memory signal lines 380 each configured to carry a specified type of memory signal. For example, the memory signal line 380 may be configured to carry a bit line (BL) signal and may be interchangeably referred to as the BL signal line 380, which may be generated by a non-memory-cell circuit, such as by a circuit (e.g., a write driver circuit and a sense amplifier) in the periphery region of an SRAM device. As discussed above with reference to FIG. 3, the BL signal line 380 may extend in the X-direction through a substantial majority of the SRAM cell array region 310. For example, the BL signal line 380 may have a dimension 520 measured in the X-direction, and the SRAM cell array region 310 as a whole may have a dimension 530 measured in the X-direction. In some embodiments, the dimension 520 is in a range between about 20 microns and about 50 microns, and the dimension 530 is in a range between about 21 microns and about 51 microns.

A relatively long length for the BL signal line 380 means that it is capable of providing the BL signal to substantially all of the SRAM cells in any given row and/or column of the array. Unfortunately, such a long length for the BL signal line 380 also leads to loading issues and/or magnified parasitics, as discussed above with reference to FIG. 3. Therefore, to alleviate these concerns, the present disclosure revises the original IC layout design 500 to generate the revised IC layout design 510A (a front side planar top view) and 510B (a back side planar top view), in which the original BL signal line 380 may be broken up into a plurality of different BL signal line segments 380A, 380B, and 380C, and additional BL signal lines 400 and 410 are implemented to help route the BL signal. Note that the revised IC layout designs 510A and 510B are portions of the same IC layout design, even though they are illustrated separately to emphasis the BL signal line 400 and the BL signal line 410, respectively. The SRAM cell array region 310 in the original IC layout design 500 is also revised into SRAM cell array region segments 310A, 310B, and 310C in the revised IC layout design 510A-510B. The revised IC layout design 510A-510B also implements the middle strap regions 390 and 391 located between the SRAM cell array region segments 310A, 310B, and 310C.

According to the revised IC layout design 510A-510B, the BL signal line segments 380A-380C each have a dimension 540 that is measured in the X-direction, where the dimension 540 is smaller than the dimension 520 of the BL signal line 380 in the original IC layout design 500. As an inherent result of the smaller length of each of the BL signal line segments 380A-380C, the loading and/or parasitics can be reduced by the revised IC layout design 510A-510B.

Furthermore, the implementation of the BL signal lines 400 and 410 can also reduce the loading and/or parasitic effects associated with the original IC layout design 500. In more detail, the BL signal line 380 in the original IC layout design 500 is implemented in the bottom interconnect layer (e.g., a metal-0 layer) of the front side interconnect structure in some embodiments, and the same is true for the BL signal line segments 380A-380C in the revised IC layout design 510A-510C. This is illustrated in FIG. 6, which is a cross-sectional side view of a portion of the electronic memory device 300, for example, at the SRAM cell array region 310. The cross-sectional side view may be taken along a vertical plane defined by the Z-direction vertically and the X-direction horizontally. The cross-sectional side view includes a device region 600, in which electrical circuitry (e.g., the SRAM cell arrays or periphery circuitry of an SRAM device) is formed using the transistors such as the FinFET or GAA devices discussed above. The cross-sectional side view also includes an interconnect structure 610 disposed over a front side of the device region 600, as well as an interconnect structure 620 disposed over a back side of the device region 600, where the back side is opposite the front side.

The interconnect structure 610 and the interconnect structure 620 may each be a multi-layer interconnect (MLI) structure that includes a plurality of interconnect layers (e.g., metal-0, metal-1, metal-2, metal-3, etc.), as well as a plurality of conductive vias that interconnect the various interconnect layers together. The interconnect layers may include a plurality of metal lines, which may be implemented as elongated conductive strips. The metal lines are configured to route electrical signals, and the metal lines from different interconnect layers are interconnected together by the conductive vias. In various embodiments, the metal lines and/or vias may contain copper, aluminum, tungsten, cobalt, ruthenium, or combinations thereof. The metal lines and conductive vias are embedded in a dielectric material that provides electrical isolation for the metal lines and/or conductive vias as appropriate. In various embodiments, the dielectric material may include silicon oxide, silicon oxynitride, silicon nitride, silicon carbide, or a low-k dielectric material having a dielectric constant lower than that of silicon oxide (e.g., less about 3.9).

Note that although FIG. 6 illustrates four interconnect layers (e.g., metal-0 through metal-3) for the front side interconnect structure 610 and one interconnect layer (e.g., B-metal-0) for the back side interconnect structure 620, this is not intended to be limiting unless otherwise claimed. In other words, the front side interconnect structure 610 may have more or fewer than the four illustrated interconnect layers, and the back side interconnect structure 620 may have more or fewer than the one illustrated interconnect layer as well. One or more of these other additional interconnect layers (e.g., other than the metal-0 layer of the front side interconnect structure 610) may also be used to implement memory signal lines such as the BL signal lines 400 and/or 410 in other embodiments.

As discussed above with reference to FIGS. 5B-5C, the metal-0 layer (e.g., one of the metal lines in this interconnect layer) of the interconnect structure 610 of FIG. 6 may be used to implement the BL signal line segments 380A-380C of the revised IC layout design 510A-510B. In comparison, the BL signal line 400 of the revised IC layout design 510A is implemented in a higher-level interconnect layer of the interconnect structure 610, such as in the metal-2 interconnect layer. Note that the metal-1 interconnect layer may not be suitable for implementing the BL signal line 400, because the metal lines in the metal-1 interconnect layer may extend in a perpendicular direction as the metal lines in the metal-0 or the metal-2 interconnect layer and therefore cannot deliver the BL signal to the SRAM cell arrays in the X-direction. As such, the BL signal line 400 is implemented two levels above the BL signal line segments 380A-380C. Meanwhile, the BL signal line 410 of the revised IC layout design 510B is implemented in an interconnect layer of the interconnect structure 620, such as in the B-metal-0 layer.

One reason for the implementing the BL signal lines 400 and 410 in different interconnect layers than the BL signal line segments 380A-380C is to optimize device performance. For example, the BL signal line 400 routes the BL signal from the periphery circuitry of the electronic memory device 300 directly to the segment 310B of the SRAM cell array region 310, which allows the BL signal to bypass the segment 310A of the SRAM cell array region 310. In other words, rather than having to travel through the BL signal line segments 380A located in the SRAM cell array region segment 310A—which would have certain loading and/or parasitics associated therewith—the BL signal can hop on a “highway” provided by the BL signal line 400 and be propagated to the segment 310B of the SRAM cell array region with less loading and/or parasitics. The BL signal line 400 herein can function similar to a “highway” not only because it has a longer dimension 550 than each of the BL signal line segments 380A-380C in the X-direction, but also because it has a thicker width measured in the Y-direction as well. For example, whereas the BL signal line segments 380A-380C may each have a width 560 (i.e., a dimension measured in the Y-direction) in the planar top view of FIGS. 5B-5C, the BL signal line 400 has a width 570 measured (also a dimension measured in the Y-direction) in the planar top view of FIGS. 5B-5C. According to various aspects of the present disclosure, the width 570 is substantially greater than the width 560. The greater width 570 inherently leads to a reduced parasitic resistance (since resistance is inversely correlated with width), as well as better uniformity (since variations in the width 570 due to fabrication process imperfections account a smaller percentage of the overall width). In some embodiments, the width 570 is in a range between about 30 nanometers (nm) and about 60 nm, and the width 560 is in a range between about 20 nm and about 60 nm. Such a range is specifically configured to ensure that the BL signal line 400 can offer the reduced parasitics while also retaining sufficient routing flexibility.

In addition to reducing parasitic resistance with the thicker width 570, the manner in which the BL signal line 400 is implemented herein may also improve device performance as an inherent result of greater spacing between adjacent pairs of BL signal lines 400. For example, whereas the BL signal line segment 380A is spaced apart from a nearest one of another BL signal line segment 380A (e.g., nearest in the Y-direction) by a distance 565, the BL signal line 400 is spaced apart from a nearest one of another BL signal line 400 by a distance 575 in the Y-direction. According to various aspects of the present disclosure, the distance 575 is substantially greater than the distance 565. The greater distance 575 may inherently lead to a reduced parasitic capacitance (since capacitance is inversely correlated with distance between two conductive plates). In some embodiments, the distance 575 is in a range between about 200 nm and about 500 nm, and the distance 565 is in a range between about 200 and about 500 nm. Such a range is also specifically configured to ensure that the BL signal line 400 can offer the reduced parasitics while also retaining sufficient routing flexibility.

Another reason that the BL signal line 400 can help reduce parasitic capacitance is inherently attributable to its location in the metal-2 interconnect layer. In other words, the BL signal line 400 is located farther from the various microelectronic components of the SRAM cell array than the BL signal line segment 380A (which is located in the metal-0 layer), and as such, any parasitic capacitive coupling between the BL signal line 400 and the other microelectronic components is inherently less significant, as parasitic capacitance is inversely proportional to distance between two conductive plates. In addition, due to the greater distance, the BL signal propagating on the BL signal line 400 is also less vulnerable for being affected by noise or other sources of interference from the SRAM cell array circuitry below, which may further improve device performance.

Still referring to FIGS. 5B-5C and 6, the BL signal line 410 may function similarly as the BL signal line 400, except that the BL signal line 410 is configured to bring the BL signal to the segment 310C of the SRAM cell array region, rather than to the segments 310A/310B of the SRAM cell array region. In other words, the BL signal can hop on a “highway” provided by the BL signal line 410 and be propagated to the segment 310C of the SRAM cell array region with less loading and/or parasitics. However, whereas the BL signal line 400 is implemented in the metal-2 interconnect layer of the front side interconnect structure 610, the BL signal line 410 is implemented in the B-metal-0 interconnect layer of the back side interconnect structure 620.

As shown in the top view of FIG. 5C, the BL signal line 410 herein also has a dimension 580 that is longer than each of the BL signal line segments 380A-380C in the X-direction, and it has a width 590 that is wider than the width 560 of each of the BL signal line segments 380A-380C in the Y-direction. Similar to what was discussed above in association with the BL signal line 400, the longer dimension 580 inherently allows the BL signal line 410 to span across and bypass the segments 310A and 310B of the SRAM cell array region, and the wider width 590 inherently allows the BL signal line 410 to have reduced parasitic resistance. In addition, since the BL signal line 410 is configured to deliver the BL signal to the farthest region (e.g., the segment 310C is farther from the periphery region than the segment 310B), the BL signal line 410 may be implemented with an even greater width than the BL signal line 400. In other words, the width 590 may be implemented to be greater than the width 570 in some embodiments. In some embodiments, the width 590 is in a range between about 30 nm and about 60 nm, and the width 570 is in a range between about 20 nm and about 60 nm. Furthermore, a distance 595 separating an adjacent pair of BL signal lines 410 is also greater than the distance 565 between an adjacent pair of the BL signal line segments 380A, which also helps to reduce parasitic capacitance associated with the BL signal line 410 for reasons similar to those discussed above in association with the BL signal line 400. In some embodiments, the distance 595 is in a range between about 200 nm and about 500 nm, and the distance 565 is in a range between about 200 and about 500 nm. Such a range is specifically configured to ensure that the BL signal line 410 can offer the reduced parasitics while also retaining sufficient routing flexibility.

As shown in FIGS. 5B-5C, the BL signal line 400 may terminate at the middle strap region 390, and the BL signal line 410 may terminate at the middle strap region 391. In some embodiments, the middle strap region 390 may include one or more conductive vias or metal lines to help establish a connection between the BL signal line 400 and the BL signal line segment 380B in the SRAM cell array region segment 310B. For example, the middle strap region 390 may include a conductive via similar to a conductive via 630 (establishing electrical connectivity between the metal lines of the metal-2 layer and the metal-1 layer) of FIG. 6, a metal line similar to a metal line 640 of the metal-1 layer, and a conductive via similar to a conductive via 650 (establishing electrical connectivity between the metal lines of the metal-1 layer and the metal-0 layer).

Similar to the middle strap region 390, the middle strap region 391 may also include one or more conductive vias or metal lines to help establish a connection between the BL signal line 410 and the BL signal line segment 380C in the segment 310C of the SRAM cell array region. For example, the conductive vias and/or metal lines of the middle strap region 391 may be similar to the conductive vias 630 and 650 and the metal line 640 of FIG. 6, except that they may be implemented in the back side interconnect structure 620.

In the embodiment of FIGS. 5A-5C, the original IC layout design 500 is revised to generate the revised IC layout design 510A-510B that comprises three segments 310A-310C of the SRAM cell array region. However, the dividing of a single continuous SRAM cell array region 310 into three segments 310A-310C is merely an example, and it is understood that the SRAM cell array region 310 may be divided into a different number of segments in other embodiments. For example, referring now to FIGS. 7A-7C, the original IC layout design 500 is revised to generate a revised IC layout design 510A-510C that comprises four segments 310A-310D of the SRAM cell array region. For reasons of simplicity, the original IC layout design 500 is omitted from FIGS. 7A-7C, since the original IC layout design 500 may remain the same as it was in FIG. 5A. In addition, similar components appearing in FIGS. 5A-5C and 7A-7C will be labeled the same for reasons of consistency and clarity.

As shown in FIGS. 7A-7C, the original IC layout design 500 is revised to generate IC layout designs 510A-510C, which are also planar top views of a horizontal plane defined by the X-direction and the Y-direction and may include a GDS file. In this embodiment, the SRAM cell array region 310 is divided into four different segments 310A, 310B, 310C, and 310D, which are separated from one another by middle strap regions 390, 391, and 392. The BL line signal segments 390A-380D (implemented in the metal-0 layer of the front side interconnect structure) are disposed in the four different segments 310A-310D of the SRAM cell array region, respectively. As discussed above, the BL signal line 400 (implemented in the metal-2 layer of the front side interconnect structure) spans across the segment 310A of the SRAM cell array region and terminates into the middle strap region 390 to provide the BL signal to the SRAM circuitry in the segment 310B of the SRAM cell array region, while bypassing the segment 310A. The BL signal line 410 (implemented in the B-metal-0 layer of the back side interconnect structure) spans across the segments 310A-310B of the SRAM cell array region and terminates into the middle strap region 391 to provide the BL signal to the SRAM circuitry in the segment 310C of the SRAM cell array region, while bypassing the segments 310A-310B.

In addition, a BL signal line 700 is implemented in a B-metal-2 layer of the back side interconnect structure. The B-metal-2 layer is located two levels below (or above, depending on the frame of reference) the B-metal-0 layer, similar to how the metal-2 layer is located two levels above the metal-0 layer of the front side interconnect structure. The BL signal line 700 spans across the segments 310A-310C of the SRAM cell array region and terminates into the middle strap region 392 to provide the BL signal to the SRAM circuitry in the segment 310D of the SRAM cell array region, while bypassing the segments 310A-310C. In other words, the BL signal line 700 may serve as a “highway” for the BL signal in a similar manner as the BL signal lines 400-410 as discussed above.

The BL signal line 700 has a dimension 710 in the X-direction, which is longer than the dimension 540 of each of the BL signal line segments 380A-380D. The BL signal line 700 also has a width 720 measured in the Y-direction, which is greater than the width 560 of the BL signal line segment 380A-380D. In some embodiments, the width 720 may be implemented to be even greater than the width 570 of the BL signal line 400 or the width 590 of the BL signal line 410, since the BL signal line 700 has to travel an even longer distance than the BL signal lines 400 or 410, which means that it may be even more beneficial to reduce the parasitic resistance of the BL signal line 700 by increasing its width 720. In some embodiments, the width 720 is in a range between about 30 nm and about 60 nm, and the width 560 is in a range between about 20 nm and about 60 nm. Furthermore, a distance 725 separating an adjacent pair of BL signal lines 700 is also greater than the distance 565 separating an adjacent pair of the BL signal line segments 380D, which also inherently helps to reduce parasitic capacitance associated with the BL signal line 700 for reasons similar to those discussed above in association with the BL signal line 400. In some embodiments, the distance 725 is in a range between about 200 nm and about 500 nm, and the distance 565 is in a range between about 200 and about 500 nm. Such a range is specifically configured to ensure that the BL signal line 700 can offer the reduced parasitics while also retaining sufficient routing flexibility.

The BL signal line 700 may terminate into the middle strap region 392, which may also include one or more conductive vias or metal lines to help establish a connection between the BL signal line 700 and the BL signal line segment 380D in the segment 310D of the SRAM cell array region. For example, the middle strap region 392 may include conductive vias similar to the conductive vias 630 and 650 in FIG. 6, except that these conductive vias may be located in the back side interconnect structure 620. The middle strap region 392 may also include a metal line similar to a metal line 640 of the metal-1 layer, except such a metal line may be located in a B-metal-1 layer of the back side interconnect structure 620 as well. In any case, through these conductive vias and/or metal lines, the BL signal line 700 may be able to bring the BL signal directly to the SRAM circuitry in the segment 310D of the SRAM cell array region, while bypassing the segments 310A-310C.

Referring now to FIGS. 8A and 8B, planar top views of a front side and a back side of a portion of an IC layout are illustrated, respectively. For example, FIG. 8A illustrates various layers of an IC layout of an SRAM cell 800 from the front side, and FIG. 8B illustrates various layers of an IC layout of the SRAM cell 800 from the back side. The SRAM cell 800 has a cell height 810 that is measured in the Y-direction. The SRAM cell 800 also includes a plurality of active regions 820 that each extend in the X-direction horizontally. The active regions 820 may include portions of the fin structures of the FinFET device or the nano-structures of the GAA device discussed above with reference to FIGS. 1A-1C. The SRAM cell 800 also includes a plurality of gate structures 830 that each extend in the Y-direction horizontally. The gate structures 830 may also include the gate structures of the FinFET device or the GAA device discussed above with reference to FIGS. 1A-1C.

The front side of the SRAM cell 800 shown in FIG. 8A includes metal lines, such as metal lines 840, 841, and 842 in the metal-0 layer. In the illustrated embodiment, the metal line 840 corresponds to a bit line (BL), the metal line 841 corresponds to a word line (WL), and the metal line 842 corresponds to a Vcc. Note that there may be some overlap (in the Y-direction) between some of the metal lines and the active regions (e.g., between the metal line 840 and the active region 820). In some embodiments, the metal line 840 may be an embodiment of one of the signal line segments 380A-380D discussed above. The metal line 840 may have a width 850 measured in the Y-direction, and it is separated from the metal lines 841 and 842 by a distance 851 and by a distance 852, respectively, in the Y-direction. For reasons of simplicity, the additional metal layers, such as metal-1 layer, the metal-2 layer, etc., are not specifically illustrated herein.

The back side of the SRAM cell 800 shown in FIG. 8B also includes the active regions 820 and gate structures 830, as well as metal lines, such as metal lines 860, 861, and 862 in the B-metal-0 layer. In the illustrated embodiment, the metal line 860 corresponds to a bit line (BL), the metal line 861 corresponds to a Vss, and the metal line 862 corresponds to a Vcc. Note that there may be some overlap (in the Y-direction) between some of the metal lines and the active regions (e.g., between the metal line 860 and the active region 820). In some embodiments, the metal line 860 may be an embodiment of one of the BL signal line 410 discussed above. The metal line 860 may have a width 870 measured in the Y-direction, and it is separated from the metal lines 861 and 862 by a distance 871 and by a distance 872, respectively, in the Y-direction. According to various aspects of the present disclosure, the width 850 is less than or equal to the width 870, which helps to reduce parasitic resistance. For reasons of simplicity, the additional metal layers, such as the B-metal-2 layer, are not specifically illustrated herein.

FIG. 9 illustrates an IC fabrication system 900 according to embodiments of the present disclosure. For example, the IC fabrication system 900 may be used to generate an IC layout design or revise an IC layout design, as well as to fabricate an IC device based on the IC layout design. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the active regions; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 10 is a flowchart illustrating a method 1000 to fabricate an electronic memory device. In some embodiments, the electronic memory device includes an SRAM device. The method 1000 includes a step 1010 to form non-memory-cell circuitry in a first region of a substrate and memory-cell circuitry in a second region of the substrate. The first region is disposed adjacent to the second region in a first horizontal direction in a planar top view. The method 1000 includes a step 1020 to form a first interconnect structure over a front side of the substrate in a cross-sectional side view. The first interconnect structure includes at least a first interconnect layer and a second interconnect layer disposed over the first interconnect layer. The first interconnect layer includes a first conductive component configured to route a predefined memory signal to the memory-cell circuitry located in a first segment of the second region. The second interconnect layer includes a second conductive component configured to route the predefined memory signal to the memory-cell circuitry located in a second segment of the second region.

The method 1000 includes a step 1030 to form a second interconnect structure over a back side of the substrate in the cross-sectional side view. The second interconnect structure includes at least a third interconnect layer. The third interconnect layer includes a third conductive component configured to route the predefined memory signal to the memory-cell circuitry located in a third segment of the second region. The third segment and the second segment are each located farther from the first region than the first segment.

In some embodiments, the first interconnect structure and the second interconnect structure are formed such that the second conductive component and the third conductive component are wider than the first conductive component in a second horizontal direction perpendicular to the first horizontal direction in the planar top view.

In some embodiments, the third segment is located farther from the first region than the second segment, and the first interconnect structure and the second interconnect structure are formed such that the third conductive component is wider than the second conductive component in the second horizontal direction.

It is understood that the method 1000 may include further steps performed before, during, or after the steps 1010-1030. For example, the method 1100 may include a step of operating the electronic memory device at least in part by generating a bit line signal as the predefined memory signal. For reasons of simplicity, these additional steps are not discussed herein in detail.

FIG. 11 is a flowchart illustrating a method 1100 of revising an IC layout design according to embodiments of the present disclosure. The method 1100 includes a step 1110 to access a first IC layout design of an electronic memory device. The first IC layout design includes: a non-memory-cell region, a memory-cell region located adjacent to the non-memory-cell region in a first horizontal direction, a first signal line extending from the non-memory-cell region into the memory-cell region in the first horizontal direction. The first signal line extends through a majority of the memory-cell region in the first horizontal direction.

The method 1100 includes a step 1120 to revise the first IC layout design into a second IC layout design. The revising includes implementing at least a second signal line and a third signal line that are configured to carry a same type of signal as the first signal line, such that the second signal line and the third signal line extend from the non-memory-cell region into different portions of the memory-cell region in the first horizontal direction. The second signal line and the third signal line are implemented at different interconnect layers than the first signal line.

In some embodiments, the revising of the first IC layout design is performed such that the second signal line and the third signal line are each implemented with a wider dimension in a second horizontal direction than the first signal line. The second horizontal direction is different from the first horizontal direction.

In some embodiments, in both the first IC layout design and the second IC layout design, the first signal line is implemented in a first interconnect layer of a front side interconnect structure of the electronic memory device. In the second IC layout design, the second signal line is implemented in a second interconnect layer of the front side interconnect structure different from the first interconnect layer, and the third signal line is implemented in a third interconnect layer of a back side interconnect structure of the electronic memory device.

In some embodiments, the revising of the first IC layout design is performed such that the third signal line has a greater dimension than the second signal line in the first horizontal direction.

In some embodiments, the revising the first IC layout design further includes implementing one or more strap regions in the memory-cell region. The one or more strap regions are configured to route electrical signals from the second signal line or the third signal line to the first signal line.

In some embodiments, the electronic memory device includes a static random access (SRAM) device, and the first signal line, the second signal line, and the third signal line are each configured to carry a bit line signal for the SRAM device.

It is understood that the method 1100 may include further steps performed before, during, or after the steps 1110-1120. For example, the method 1100 may include a step of fabricating an electronic memory device according to the second IC layout design. For reasons of simplicity, these additional steps are not discussed herein in detail.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

In summary, the present disclosure implements additional memory device signal lines (e.g., BL signal lines) located in other interconnect layers to help route a specified memory device signal (e.g., a BL signal) to different regions of an SRAM cell array. For example, the SRAM cell array region may be divided into three regions: a near region, an intermediate region, and a far region, with respect to a periphery circuit region that generated the specified memory device signal. In some embodiments, a metal line from a metal-0 layer of a front side interconnect structure is used to route the specified memory device signal to the near region, a metal line from a metal-2 layer of the front side interconnect structure is used to route the specified memory device signal to the intermediate region, and a metal line from a B-metal-0 layer of a back side interconnect structure is used to route the specified memory device signal to the far region.

Such an implementation scheme of the present disclosure may offer certain advantages. However, it is understood that not all advantages are discussed herein, different embodiments may offer different advantages, and that no particular advantage is required for any embodiment. One advantage is that loading may be reduced. For example, a BL signal line extending through a long SRAM cell array (e.g., greater than 128 bits) may lead to loading issues. By breaking up the long BL signal line into a plurality of smaller segments, the loading issues may be reduced. Another advantage is that the parasitic resistance may be reduced. For example, the BL signal lines implemented in the metal-2 layer of the front side interconnect structure or in the B-metal-0 layer of the back side interconnect structure each have a wider width than the BL signal lines in the metal-0 layer of the front side interconnect structure. Since a width of a metal line is inversely correlated with its parasitic resistance, the wider width of these additional BL signal lines may inherently lead to lower parasitic resistance. Yet another advantage is that the parasitic capacitance may be reduced. For example, the BL signal lines in either the metal-2 layer of the front side interconnect structure or in the B-metal-0 layer of the back side interconnect structure may be spaced farther apart from the nearest BL signal line in that layer, and since a spacing between two metal line is inversely correlated with its parasitic capacitance, the greater spacing between these BL signal lines may inherently lead to lower parasitic capacitance. Furthermore, the location of these BL signal lines (e.g., not in the metal-0 layer of the front side interconnect structure) inherently results in a greater separation between the BL signal lines and other conductive components located in the SRAM array circuitry, which also helps to reduce the parasitic capacitance. As a result of the reduced device parasitics, device performance such as speed and/or power consumption may be improved. Other advantages may include compatibility with existing fabrication processes (including for both FinFET and GAA processes) and the ease and low cost of implementation.

It is understood that although these concepts of the present disclosure are discussed using an electronic memory device as an example, they are not intended to be limited to an electronic memory device unless otherwise claimed. The concepts of implementing additional signal lines in various interconnect layers to help route electronic signals may apply to other suitable IC applications as well.

One aspect of the present disclosure pertains to an electronic memory device. The electronic memory device includes a non-memory-cell region that includes non-memory-cell circuitry formed at least partially in a substrate. The electronic memory device includes a memory-cell region that includes memory-cell circuitry formed at least partially in the substrate. The memory-cell region includes at least a first segment, a second segment, and a third segment. The first segment is located closest to the non-memory-cell region in a top view. The second segment and the third segment are each located farther from the non-memory-cell region than the first segment in the top view. The electronic memory device further includes a first interconnect structure disposed over a first side of the substrate in a cross-sectional side view. The first interconnect structure includes at least a first interconnect layer and a second interconnect layer. The first interconnect layer is configured to route a specified type of memory signal from the non-memory-cell region to the first segment of the memory-cell region. The second interconnect layer is configured to route the specified type of memory signal from the non-memory-cell region to the second segment of the memory-cell region. The electronic memory device further includes a second interconnect structure disposed over a second side of the substrate in the cross-sectional side view. The second side is different from the first side. The second interconnect structure includes at least a third interconnect layer. The third interconnect layer is configured to route the specified type of memory signal from the non-memory-cell region to the third segment of the memory-cell region.

One aspect of the present disclosure pertains to a method of fabricating an electronic memory device. A non-memory-cell circuitry is formed in a first region of a substrate and memory-cell circuitry in a second region of the substrate. The first region is disposed adjacent to the second region in a first horizontal direction in a planar top view. A first interconnect structure is formed over a front side of the substrate in a cross-sectional side view. The first interconnect structure includes at least a first interconnect layer and a second interconnect layer disposed over the first interconnect layer, wherein the first interconnect layer includes a first conductive component configured to route a predefined memory signal to the memory-cell circuitry located in a first segment of the second region. The second interconnect layer includes a second conductive component configured to route the predefined memory signal to the memory-cell circuitry located in a second segment of the second region. A second interconnect structure is formed over a back side of the substrate in the cross-sectional side view. The second interconnect structure includes at least a third interconnect layer. The third interconnect layer includes a third conductive component configured to route the predefined memory signal to the memory-cell circuitry located in a third segment of the second region. The third segment and the second segment are each located farther from the first region than the first segment.

Yet another aspect of the present disclosure pertains to a method of revising an IC layout design. A first IC layout design of an electronic memory device is accessed. The first IC layout design includes: a non-memory-cell region; a memory-cell region located adjacent to the non-memory-cell region in a first horizontal direction; and a first signal line extending from the non-memory-cell region into the memory-cell region in the first horizontal direction, wherein the first signal line extends through a majority of the memory-cell region in the first horizontal direction. The first IC layout design is revised into a second IC layout design. The revising includes implementing at least a second signal line and a third signal line that are configured to carry a same type of signal as the first signal line, such that the second signal line and the third signal line extend from the non-memory-cell region into different portions of the memory-cell region in the first horizontal direction. The second signal line and the third signal line are implemented at different interconnect layers than the first signal line.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An electronic memory device, comprising:
a non-memory-cell region that includes non-memory-cell circuitry formed at least partially in a substrate;
a memory-cell region that includes memory-cell circuitry formed at least partially in the substrate, wherein the memory-cell region includes at least a first segment, a second segment, and a third segment, wherein the first segment is located closest to the non-memory-cell region in a top view, wherein the second segment and the third segment are each located farther from the non-memory-cell region than the first segment in the top view;
a first interconnect structure disposed over a first side of the substrate in a cross-sectional side view, wherein the first interconnect structure includes at least a first interconnect layer and a second interconnect layer, wherein the first interconnect layer is configured to route a specified type of memory signal from the non-memory-cell region to the first segment of the memory-cell region, and wherein the second interconnect layer is configured to route the specified type of memory signal from the non-memory-cell region to the second segment of the memory-cell region; and
a second interconnect structure disposed over a second side of the substrate in the cross-sectional side view, wherein the second side is different from the first side, wherein the second interconnect structure includes at least a third interconnect layer, and wherein the third interconnect layer is configured to route the specified type of memory signal from the non-memory-cell region to the third segment of the memory-cell region.

2. The electronic memory device of claim 1, wherein:
the electronic memory device includes a static random access memory (SRAM) device; and
the specified type of memory signal includes a bit line signal for the SRAM device.

3. The electronic memory device of claim 1, wherein the third segment is located farther from the non-memory-cell region than the second segment in the top view.

4. The electronic memory device of claim 3, wherein:
the memory-cell region further includes a fourth segment;
the fourth segment is located farther from the non-memory-cell region than the third segment in the top view;
the second interconnect structure further includes a fourth interconnect layer; and
the fourth interconnect layer is configured to route the specified type of memory signal from the non-memory-cell region to the fourth segment of the memory-cell region.

5. The electronic memory device of claim 1, wherein:
the first interconnect layer includes a first conductive component configured to route the specified type of memory signal from the non-memory-cell region to the first segment of the memory-cell region;
the second interconnect layer includes a second conductive component configured to route the specified type of memory signal from the non-memory-cell region to the second segment of the memory-cell region;
the third interconnect layer includes a third conductive component configured to route the specified type of memory signal from the non-memory-cell region to the third segment of the memory-cell region; and
the third conductive component has a greater lateral dimension than the second conductive component in the top view.

6. The electronic memory device of claim 5, wherein:
the first conductive component, the second conductive component, and the third conductive component each extends in a first direction in the top view;
the second conductive component has a greater dimension than the first conductive component in the first direction in the top view; and
the third conductive component has a greater dimension than the second conductive component in the first direction in the top view.

7. The electronic memory device of claim 6, wherein the second conductive component and the third conductive component each have a greater dimension than the first conductive component in a second direction perpendicular to the first direction in the top view.

8. The electronic memory device of claim 5, wherein:
the first interconnect layer further includes a fourth conductive component located in the second segment and a fifth conductive component located in the third segment of the memory-cell region;
the memory-cell region further includes a first strap region located between the first segment and the second segment of the memory-cell region and a second strap region located between the second segment and the third segment of the memory-cell region;
the first strap region includes one or more first conductive vias that facilitate a routing of the specified type of memory signal from the second conductive component of the second interconnect layer to the fourth conductive component of the first interconnect layer; and
the second strap region includes one or more second conductive vias that facilitate a routing of the specified type of memory signal from the third conductive component of the third interconnect layer to the fifth conductive component of the first interconnect layer.

9. The electronic memory device of claim 1, wherein:
the first interconnect structure further includes an additional interconnect layer disposed between the first interconnect layer and the second interconnect layer in the cross-sectional side view; and
the additional interconnect layer is free of including conductive components that route the specified type of memory signal.

10. The electronic memory device of claim 1, wherein the non-memory-cell region includes input/output circuitry as the non-memory-cell circuitry for the electronic memory device.

11. A method of fabricating an electronic memory device, comprising:
forming non-memory-cell circuitry in a first region of a substrate and memory-cell circuitry in a second region of the substrate, wherein the first region is disposed adjacent to the second region in a first horizontal direction in a planar top view;
forming a first interconnect structure over a front side of the substrate in a cross-sectional side view, wherein the first interconnect structure includes at least a first interconnect layer and a second interconnect layer disposed over the first interconnect layer, wherein the first interconnect layer includes a first conductive component configured to route a predefined memory signal to the memory-cell circuitry located in a first segment of the second region, and wherein the second interconnect layer includes a second conductive component configured to route the predefined memory signal to the memory-cell circuitry located in a second segment of the second region; and
forming a second interconnect structure over a back side of the substrate in the cross-sectional side view, wherein the second interconnect structure includes at least a third interconnect layer, wherein the third interconnect layer includes a third conductive component configured to route the predefined memory signal to the memory-cell circuitry located in a third segment of the second region, wherein the third segment and the second segment are each located farther from the first region than the first segment.

12. The method of claim 11, wherein the first interconnect structure and the second interconnect structure are formed such that the second conductive component and the third conductive component are wider than the first conductive component in a second horizontal direction perpendicular to the first horizontal direction in the planar top view.

13. The method of claim 12, wherein:
the third segment is located farther from the first region than the second segment; and
the first interconnect structure and the second interconnect structure are formed such that the third conductive component is wider than the second conductive component in the second horizontal direction.

14. The method of claim 11, further comprising operating the electronic memory device at least in part by generating a bit line signal as the predefined memory signal.

15. A method, comprising:
accessing a first IC layout design of an electronic memory device, wherein the first IC layout design includes:
a non-memory-cell region;
a memory-cell region located adjacent to the non-memory-cell region in a first horizontal direction; and
a first signal line extending from the non-memory-cell region into the memory-cell region in the first horizontal direction, wherein the first signal line extends through a majority of the memory-cell region in the first horizontal direction; and
revising the first IC layout design into a second IC layout design, wherein the revising includes implementing at least a second signal line and a third signal line that are configured to carry a same type of signal as the first signal line, such that the second signal line and the third signal line extend from the non-memory-cell region into different portions of the memory-cell region in the first horizontal direction, wherein the second signal line and the third signal line are implemented at different interconnect layers than the first signal line.

16. The method of claim 15, wherein the revising the first IC layout design is performed such that the second signal line and the third signal line are each implemented with a wider dimension in a second horizontal direction than the first signal line, wherein the second horizontal direction is different from the first horizontal direction.

17. The method of claim 15, wherein:
in both the first IC layout design and the second IC layout design, the first signal line is implemented in a first interconnect layer of a front side interconnect structure of the electronic memory device; and
in the second IC layout design, the second signal line is implemented in a second interconnect layer of the front side interconnect structure different from the first interconnect layer, and the third signal line is implemented in a third interconnect layer of a back side interconnect structure of the electronic memory device.

18. The method of claim 15, wherein the revising the first IC layout design is performed such that the third signal line has a greater dimension than the second signal line in the first horizontal direction.

19. The method of claim 15, wherein the revising the first IC layout design further includes implementing one or more strap regions in the memory-cell region, wherein the one or more strap regions are configured to route electrical signals from the second signal line or the third signal line to the first signal line.

20. The method of claim 15, wherein:
the electronic memory device includes a static random access (SRAM) device; and
the first signal line, the second signal line, and the third signal line are each configured to carry a bit line signal for the SRAM device.
